(19) United States
(12) Patent Application Publication
(10) Pub. No.: US 2026/0172012 A1
(43) Pub. Date: Jun. 18, 2026

(54) MULTI-MODE SENSOR, SYSTEM-ON-CHIP COMPRISING THE SAME AND MULTI-MODE SENSING METHOD THEREOF

(71) Applicant: SAMSUNG ELECTRONICS CO., LTD., Suwon-si (KR)

(72) Inventors: Hyunki JUNG, Suwon-si (KR); Jaewook KANG, Suwon-si (KR); Young Hoon PARK, Suwon-si (KR); Huichang EOM, Suwon-si (KR); Seungjin KIM, Suwon-si (KR); Seunghyun OH, Suwon-si (KR)

(73) Assignee: SAMSUNG ELECTRONICS CO., LTD., Suwon-si (KR)

(21) Appl. No.: 19/394,188

(22) Filed: Nov. 19, 2025

(30) Foreign Application Priority Data
Dec. 13, 2024 (KR) 10-2024-0185472

(51) Int. Cl. H03K 5/134; G01R 31/317; H03K 5/00; H03K 5/131; H03K 5/156

(52) U.S. Cl. CPC H03K 5/134; G01R 31/31709; H03K 5/131; H03K 5/156; H03K 2005/00058; H03K 2005/00247

(57) ABSTRACT

A multi-mode sensor is disclosed. The sensor includes a pulse generator configured to generate at least one of a clock signal, a step pulse signal, and a window signal based on a selected sensing mode. The sensor further includes a delay chain configured to output delay clock signals transmitted through a plurality of delay elements in response to the clock signal or the step pulse signal, and a window signal defining a selection interval. An adder is configured to count the number of selected delay clock signals and output a corresponding count value. The sensing mode includes one of: a jitter sensing mode for detecting jitter in the clock signal, a processor corner sensing mode for evaluating a timing characteristic of the delay elements, and a duty ratio sensing mode for determining a duty ratio of the clock signal.

### CROSS-REFERENCE TO RELATED APPLICATIONS

This application claims priority under 35 U.S.C. § 119 to Korean Patent Application No. 10-2024-0185472 filed on Dec. 13, 2024 with the Korean Intellectual Property Office, the disclosures of which are incorporated by reference herein in their entireties.

### BACKGROUND

Embodiments of the present disclosure described herein relates to a semiconductor device, and more specifically, to a reference voltage generation circuit and a reference voltage generation method thereof.

Recently, the types and number of sensors used in mobile systems are increasing. In addition to the computational blocks for core functions, heterogeneous sensors with different functions must be integrated in the system-on-chip SoC applied to the mobile system. In the mobile system, various sensors are designed to monitor the surrounding conditions or the internal status of the mobile device. For this reason, the types and number of sensors required in the system-on-chip SoC are rapidly increasing. As the number of integrated sensors increases, the size of the power consumed by the system-on-chip SoC and the chip area occupied by each sensor also increase.

### SUMMARY

Embodiments of the present disclosure provides a system-on-chip capable of improving chip area efficiency and power efficiency by applying a multi-mode sensor in which one sensor performs different sensing operations depending on the mode.

According to an embodiment of the inventive concept, a multi-mode sensor, comprising, a pulse generator configured to generate at least one of a clock signal, a step pulse signal, and a window signal according to a sensing mode, a delay chain configured to select and output delay clock signals that are transmitted through each of a plurality of delay elements by being triggered by the clock signal or the step pulse signal as much as the pulse width of the window signal, and an adder configured to count and output the number of the selected short pulses, wherein the sensing mode includes one of a jitter sensing mode for sensing jitter of the clock signal, a processor corner sensing mode for sensing processor corner of the plurality of delay elements, and a duty ratio sensing mode for sensing a duty ratio of the clock signal.

According to an embodiment of the inventive concept, a multi-mode sensing method of a sensor mounted on a system-on-chip, comprising, receiving one of a plurality of sensing modes, generating at least one of a clock signal, a step pulse signal, and a window signal according to the received sensing mode, generating short pulses that are triggered by the clock signal or the step pulse signal to propagate through a plurality of delay elements, selecting delay clock signals delayed by the plurality of delay elements by a pulse width of the window signal, and counting and outputting the number of the selected delay clock signals.

According to an embodiment of the inventive concept, a system-on-chip, comprising, a central processing unit, and a multi-mode sensor configured to executes one of a plurality of sensing modes according to a sensing mode provided from the central processing unit and output an execution result of the one of the sensing modes as an output signal, wherein the multi-mode sensor comprises, a pulse generator configured to generate at least one of a clock signal, a step pulse signal, and a window signal according to the sensing mode, a delay chain configured to select and output delay clock signals that are transmitted through each of a plurality of delay elements by being triggered by the clock signal or the step pulse signal as much as the pulse width of the window signal, and an adder configured to count the number of the selected delay clock signals to output the number of the selected delay clock signals as the output signal, wherein the plurality of sensing modes include a jitter sensing mode for sensing jitter of the clock signal, a processor corner sensing mode for sensing processor corner of the plurality of delay elements, and a duty ratio sensing mode for sensing a duty ratio of the clock signal.

### BRIEF DESCRIPTION OF THE DRAWINGS

The above and other objects and features of the present disclosure will become apparent by describing in detail embodiments thereof with reference to the accompanying drawings.

FIG. 1 is a block diagram showing a system-on-chip according to an embodiment of the present invention.

FIG. 2 is a block diagram showing a multi-mode sensor of FIG. 1.

FIG. 3 is a block diagram showing the setup and configuration of the multi-mode sensor of FIG. 2 in a jitter sensing mode.

FIG. 4 is a waveform diagram showing the operation of the multi-mode sensor in a jitter sensing mode (JS_Mode).

FIG. 5 is a block diagram showing the setup and configuration of the multi-mode sensor of FIG. 2 in a processor corner sensing mode (PCS_Mode).

FIG. 6 is a waveform diagram showing the operation of the multi-mode sensor in a processor corner sensing mode (PCS_Mode).

FIG. 7 is a waveform diagram showing an exemplary method of detecting a processor corner PC according to an output signal of an adder of FIG. 6.

FIG. 8 is a block diagram showing the setup and configuration of the multi-mode sensor of FIG. 2 in a duty ratio sensing mode.

FIG. 9 is a waveform diagram showing the operation of a multi-mode sensor in a duty ratio sensing mode (DRS_Mode).

FIG. 10 is a flowchart showing the operation procedure according to the sensing mode (S_Mode) of a multi-mode sensor according to an embodiment of the present invention.

### DETAILED DESCRIPTION

It is to be understood that both the foregoing general description and the following detailed description are exemplary, and it is to be considered that an additional description of the claimed invention is provided. Reference signs are indicated in detail in preferred embodiments of the present invention, examples of which are indicated in the reference drawings. Wherever possible, the same reference numbers are used in the description and drawings to refer to the same or like parts.

Hereinafter, a multi-mode sensor that performs sensing operations according to various sensing modes based on a jitter sensor will be described. However, those skilled in the art will easily understand other advantages and performances of the present invention based on the contents described herein. The present invention may be implemented or applied through other embodiments. Furthermore, the detailed description may be modified or changed according to perspectives and applications without significantly departing from the scope, technical idea, and other purposes of the present invention.

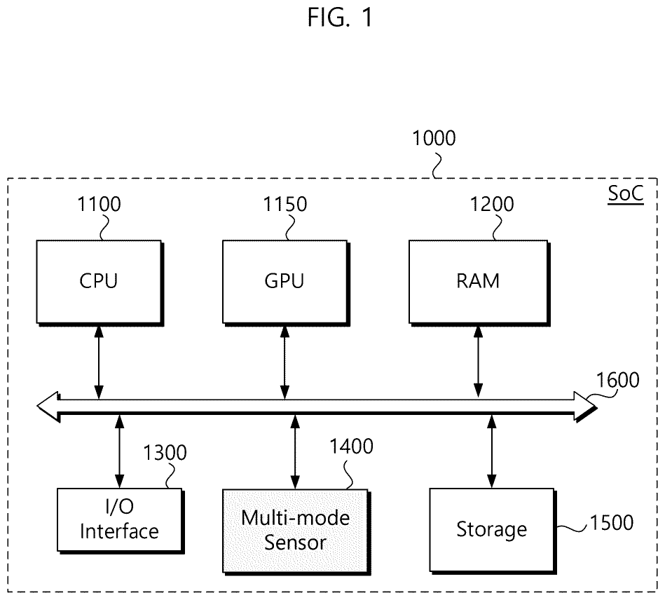

FIG. 1 is a block diagram showing a system-on-chip according to an embodiment of the present invention. Referring to FIG. 1, the system-on-chip 1000 of the present invention may include a CPU 1100, a GPU 1150, a RAM 1200, an input/output interface 1300, a multi-mode sensor 1400, a storage 1500, and a system bus 1600.

The CPU 1100 executes software (e.g., application programs, operating systems, device drivers) to be executed in the system-on-chip 1000. The CPU 1100 will execute an operating system (OS, not shown) loaded in the RAM 1200. The CPU 1100 will execute various application programs to be driven based on the operating system OS. The CPU 1100 can perform a monitoring operation for checking the function or performance of the system-on-chip 1000. In this case, the CPU 1100 can transmit a sensing request to the multi-mode sensor 1400. At this time, the CPU 1100 can provide at least one of the sensing mode to be performed by the multi-mode sensor 1400, input clock signal, and control signals.

The GPU 1150 performs various graphic operations or parallel processing operations. In other words, the GPU 1150 has a computational structure that is advantageous for parallel processing that repeatedly processes similar operations. Therefore, recently, the GPU 1150 has a structure that can be used for various operations that require high-speed parallel processing as well as graphic operations. For example, the GPU 1150 that performs general-purpose operations other than graphic processing is called a GPGPU (General Purpose computing on Graphics Processing Units).

The operating system OS or application programs will be loaded into the RAM 1200. When the system-on-chip 1000 is booted, an OS image (not shown) stored in the storage 1500 will be loaded into the RAM 1200 according to the boot sequence. Various input/output operations of the system-on-chip 1000 can be supported by the operating system OS. Similarly, application programs selected by the user or for providing basic services can be loaded into the RAM 1200. RAM 1200 may be a volatile memory such as SRAM (Static Random Access Memory) or DRAM (Dynamic Random Access Memory), or a nonvolatile memory such as PRAM, MRAM, ReRAM, FRAM, NOR flash memory.

The input/output interface 1300 controls user input and output from user interface devices. For example, the input/output interface 1300 may receive commands or data from a user through a touchpad.

The multi-mode sensor 1400 executes one of a plurality of sensing modes according to a request from the CPU 1100 or a separate management processor. The multi-mode sensor 1400 may transmit the result of the executed sensing mode to the CPU 1100 or another processor. For example, the multi-mode sensor 1400 may generate a pulse for jitter sensing in the jitter sensing mode to sense the presence of jitter in the clock signal. On the other hand, the multi-mode sensor 1400 generates a clock signal or pulse signal for detecting the processor corner PC of the system-on-chip 1000 in the processor corner (hereinafter, PC) sensing mode. Then, the multi-mode sensor 1400 performs delay counting to determine the processor corner PC of the system-on-chip 1000 using the generated clock signal or pulse signal. Then, the multi-mode sensor 1400 may transmit the counted value to the CPU 1100 or another processor. In another embodiment, the multi-mode sensor 1400 may execute a duty ratio (hereinafter, DR) sensing mode. In this way, the multi-mode sensor 1400 can execute any one sensing mode requested among a plurality of sensing modes. These embodiments will be described in more detail through the drawings described below. The storage 1500 is provided as a storage medium of the system-on-chip 1000.

The storage 1500 may store application programs, operating system images, and various data. The storage 1500 may be provided as a memory card (MMC, eMMC, SD, MicroSD, etc.) or a hard disk drive HDD. The storage 1500 may include a NAND flash memory having a large storage capacity. Alternatively, the storage 1500 may include a next-generation nonvolatile memory such as PRAM, MRAM, ReRAM, FRAM, or a NOR flash memory.

The system bus 1600 is a system bus for providing a network within the system-on-chip 1000. Through the system bus 1600, the CPU 1100, the GPU 1150, the RAM 1200, the input/output interface 1300, the multi-mode sensor 1400, and the storage 1500 are connected and can exchange data with each other. However, the configuration of the system bus 1600 is not limited to the above-described description, and may further include arbitration means for efficient management.

According to the above description, the system-on-chip 1000 includes a multi-mode sensor 1400 that executes one of a plurality of sensing modes using one sensing function block (e.g., IP). Therefore, according to these features, the system-on-chip 1000 of the present invention may reduce the chip area occupied by the sensor. In addition, the system-on-chip 1000 of the present invention may improve the power efficiency consumed by applying the multi-mode sensor 1400.

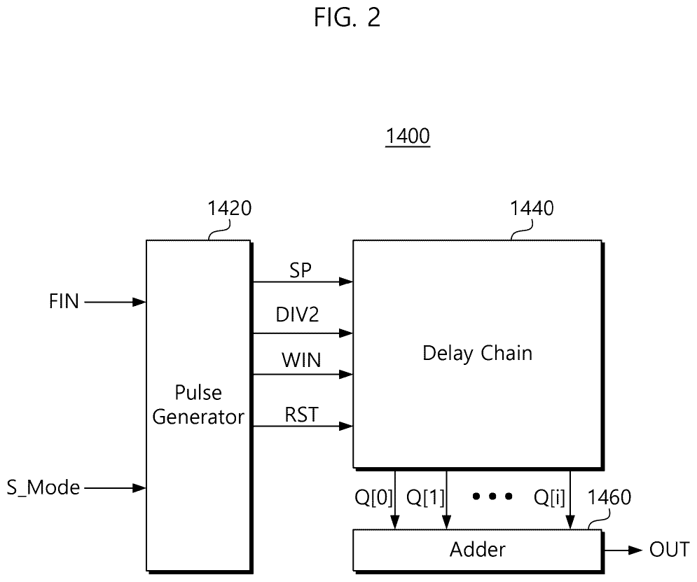

FIG. 2 is a block diagram showing the multi-mode sensor of FIG. 1. Referring to FIG. 2, the multi-mode sensor 1400 may include a pulse generator 1420, a delay chain 1440, and an adder 1460.

The pulse generator 1420 may receive an input clock signal FIN and may generate a step pulse SP, a divided clock signal DIV2, a window signal WIN, and a reset signal RST according to the mode. The divided clock signal DIV2, the window signal WIN, and the reset signal RST generated by the pulse generator 1420 may be synchronized with the input clock signal FIN. For example, the divided clock signal DIV2 may be generated by dividing the input clock signal FIN. And the window signal WIN or the reset signal RST can be activated or deactivated in synchronization with the rising edge or falling edge of the input clock signal FIN.

In particular, the pulse generator 1420 can variably generate the step pulse SP, the divided clock signal DIV2, the window signal WIN, and the reset signal RST to perform different sensing operations according to the sensing mode S_Mode. For example, when the jitter sensing mode JS_Mode is requested, the pulse generator 1420 can generate the divided clock signal DIV2 and the window signal WIN to drive the delay chain 1440 in the jitter sensing mode JS_Mode. Alternatively, when the processor corner sensing mode PCS_Mode is requested, the pulse generator 1420 can generate the step pulse SP, the mode activation signal PD, the reset signal RST, and the window signal WIN to drive the delay chain 1440 in the processor corner sensing mode PCS_Mode. The pulse generator 1420 can generate the divided clock signal DIV2 and the window signal WIN to drive the delay chain 1440 in the duty ratio sensing mode DRS_Mode when the duty ratio sensing mode DRS_Mode is requested. The signal generation for each mode of the pulse generator 1420 will be described in more detail through the drawings described below.

The delay chain 1440 can receive at least one of the step pulse SP, the divided clock signal DIV2, the window signal WIN, and the reset signal RST from the pulse generator 1420 according to the sensing mode S_Mode. The delay chain 1440 can generate a plurality of delay clock signals (CK[i], where ‘I’ is an integer greater than or equal to 0). The delay chain 1440 may include a plurality of serially connected delay elements (e.g., flip-flops), and the divided clock signal DIV2 or the step pulse SP may be input to a first delay element among the plurality of delay elements. Each of the plurality of delay clock signals (CK[i]) may be an output signal of each of the plurality of delay elements. In addition, the delay chain 1440 generates latch signals (Q[i]) that latch each of the plurality of delay clock signals (CK[i]) during a specific window period. The latch signals (Q[i]) will be counted in the adder 1460 by a different window period depending on the sensing mode S_Mode.

The adder 1460 receives the latch signals (Q[i]) from the delay chain 1440. In particular, the latch signals (Q[i]) are selected during the different window period WIN depending on the sensing mode S_Mode. Therefore, the adder 1460 counts the selected latch signals (Q[i]) according to the sensing mode S_Mode or according to the window period WIN selected by the delay chain 1440 and provides them as output signals OUT.

Here, the pulse generator 1420, the delay chain 1440, and the adder 1460 are exemplarily described as the configuration of the multi-mode sensor 1400, but the present invention is not limited to the disclosure herein. The multi-mode sensor 1400 may further include, for example, a block that quantitatively calculates the sensing result based on the output signal OUT of the adder 1460, or a block that determines whether it is Pass/Fail.

According to the multi-mode sensor 1400 described above, one of the multiple sensing modes can be selectively executed using one hardware. Therefore, it is possible to reduce the chip area occupied by the sensor and the power consumed by the sensor.

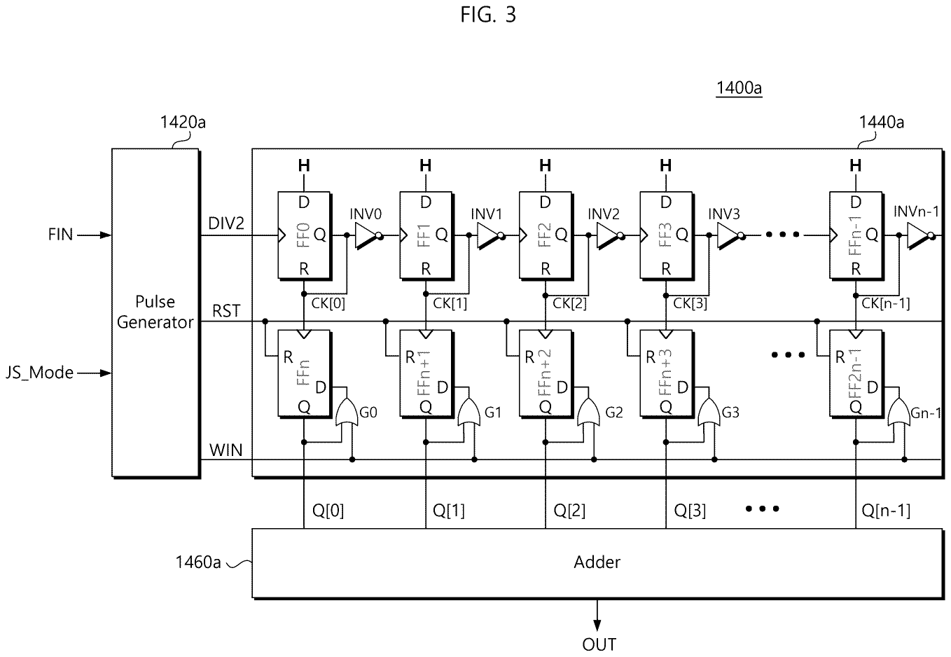

FIG. 3 is a block diagram briefly showing the setup and configuration of the multi-mode sensor of FIG. 2 in the jitter sensing mode. Referring to FIG. 3, the multi-mode sensor 1400a operates as a jitter sensor that detects jitter for an input clock signal FIN in response to the jitter sensing mode JS_Mode. The multi-mode sensor 1400a includes a pulse generator 1420a, a delay chain 1440a, and an adder 1460a for jitter sensing.

The jitter of the input clock signal FIN may vary depending on various factors. For example, the input clock signal FIN may vary due to PVT (Process, Voltage, Temperature) variation. That is, even if digital circuits are designed and manufactured identically, different jitter of the input clock signal FIN may occur for each die due to the variation of the semiconductor manufacturing process. The jitter of the input clock signal FIN may increase or decrease due to temperature, voltage, or process changes of the digital circuit.

The pulse generator 1420a receives the input clock signal FIN in response to the jitter sensing mode JS_Mode and generates a divided clock signal DIV2, a reset signal RST, and a window signal WIN. The divided clock signal DIV2, the reset signal RST, and the window signal WIN generated by the pulse generator 1420a may be synchronized with the input clock signal FIN. For example, the divided clock signal DIV2 may be generated by dividing the input clock signal FIN. The reset signal RST or the window signal WIN may be activated or deactivated in synchronization with the edge of the input clock signal FIN. For example, as illustrated in FIG. 2, in order to measure the period of the input clock signal FIN, the pulse generator 1420 may generate a window signal WIN having a pulse width equal to the period of the input clock signal FIN.

The delay chain 1440a may receive a divided clock signal DIV2 from the pulse generator 1420a and generate a plurality of delay clock signals CK[0] to CK[n-1]. The delay chain 1440a may include a plurality of serially connected delay flip-flops FF0 to FFn-1 and inverters INV0 to INVn-1. The delay flip-flops FF0 to FFn-1 provided as delay elements may be configured as, for example, D flip-flops that transfer a data input terminal ‘D’ to a data output terminal ‘Q’ on the rising edge of an input clock signal. Each of the delay flip-flops FF0 to FFn-1 generates a short pulse STP with a specific delay size ‘tD’ from a clock signal provided to a clock input terminal and transmits it to the data output terminal ‘Q’. At this time, the short pulses STP generated by each of the delay flip-flops FF0 to FFn-1 correspond to a plurality of delay clock signals CK[0] to CK[n-1]. The delay clock signal CK[i] generated in one delay flip-flop FFi is inverted by an inverter INVi and transmitted to the clock input terminal of the next delay flip-flop FFi+1. In addition, the delay clock signal CK[i] generated in the delay flip-flop FFi is fed back to the reset input terminal ‘R’ of the flip-flop FFi for reset. In addition, the delay clock signal CK[i] generated from the delay flip-flop FFi is transmitted to the clock input terminal of the lower latch flip-flop FFn+i provided for the latch.

Based on the structure of the above-described serially connected delay flip-flops FF0 to FFn-1 and inverters INV0 to INVn-1, the divided clock signal DIV2 can be input to the first delay flip-flop FF0. The delay flip-flop FF0 generates a delay clock signal CK[0] corresponding to a specific delay size ‘tD’ for the divided clock signal DIV2 and transmits it to the clock input terminal of the next delay flip-flop FF1. Like the delay flip-flop FF0, the delay flip-flop FF1 also generates a delay clock signal CK[1] having a specific delay size ‘tD’ for the delay clock signal CK[0]. In this way, the delay clock signals CK[0] to CK[n-1] generated from each of the delay flip-flops FF0 to FFn-1 can be generated within one cycle of the divided clock signal DIV2.

The latch flip-flops FFn to FF2n-1 and the gates G0 to Gn-1 located below the delay flip-flops FF0 to FFn-1 latch each of the delay clock signals CK[0] to CK[n-1]. The latch flip-flops FFn to FF2n-1 and the gates G0 to Gn-1 perform a latch function for the delay clock signals CK[0] to CK[n-1] and provide the latched latch signals Q[0] to Q[n-1] to the adder 1460a. For example, the first latch flip-flop FFn is triggered by the rising edge of the delay clock signal CK[0] and reset by the reset signal RST. The logical OR operation of the window signal WIN and the output terminal ‘Q’ is input to the data input terminal ‘D’ of the latch flip-flop FFn by the gate G0. In simple terms, the latch flip-flop FFn provides the delay clock signal CK[0] as a latch signal Q[0] to the adder 1460a when the window signal WIN is at a high level. The latch function of the latch flip-flop FFn and the gate G0 for the delay clock signal CK[0] is also performed by the latch flip-flops FFn+1 to FF2n-1 and the gates G1 to Gn-1 that latch the delay clock signals CK[1] to CK[n-1], respectively.

The adder 1460a receives latch signals Q[0] to Q[n-1] from latch flip-flops FFn to FF2n-1. The adder 1460a provides an adder or counter function for the latch signals Q[0] to Q[n-1]. The adder 1460a can output a count result for the latch signals Q[0] to Q[n-1] as an output signal OUT. The adder 1460a can count the number of those selected by a window signal WIN among the latch signals Q[0] to Q[n-1].

In conclusion, the multi-mode sensor 1400a counts the number of delay clock signals CK[i] existing within the window signal WIN having the period of the input clock signal FIN in the jitter sensing mode JS_Mode. The number of delay clock signals CK[i] existing within the pulse width of the window signal WIN is used to calculate the ratio with the total number (n-1) of delayed flip-flops FF0 to FFn-1 of the delay chain 1440a. At this time, if the ratio of the number of delay clock signals CK[i] exceeds the reference value, it can be determined that jitter exists. However, the point in time at which the number of delay clock signals CK[i] is counted in the jitter sensing mode JS_Mode must be after the divided clock signal DIV2 is input from the first delayed flip-flop FF0 and propagated to the final delayed flip-flop FFn-1.

As described above, a circuit that converts a time interval of a specific section into a digital value may be referred to as a Time-to-Digital Converter TDC. In particular, a circuit that converts a time interval into a digital value by using delay clock signals CK[0] to CK[n-1] having a plurality of different delays may be referred to as a stochastic TDC.

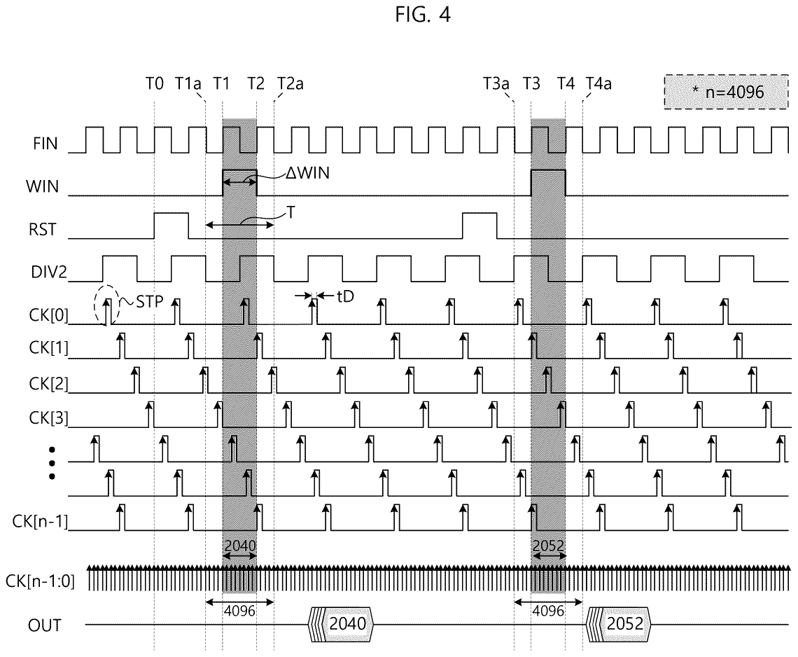

FIG. 4 is a waveform diagram showing the operation of a multi-mode sensor in the jitter sensing mode JS_Mode. Referring to FIG. 4, a divided clock signal DIV2 of an input clock signal FIN sequentially passes through the delay flip-flops FF0 to FFn-1 to generate delay clock signals CK[0] to CK[n-1]. For convenience of explanation, it is assumed that the number ‘n’ of the delay flip-flops FF0 to FFn-1 is 4096.

Each of the delay flip-flops FF0 to FFn-1 generates short pulses STP with a specific delay size ‘tD’ in cycles of the divided clock signal DIV2. That is, one short pulse STP can be generated for each cycle of the divided clock signal DIV2. The short pulse STP generated from the delay flip-flop FF0 corresponds to the delay clock signals CK[0], and the short pulse STP generated from the delay flip-flop FF1 corresponds to CK[1]. And the short pulse STP generated from the last delay flip-flop FFn-1 corresponds to CK[n-1]. Therefore, if the number of short pulses of each of the delay clock signals CK[0] to CK[n-1] is counted within one period of the divided clock signal DIV2, it will be ‘4096’ corresponding to the number of delay flip-flops FF0 to FFn-1.

For jitter sensing, the multi-mode sensor 1400a activates the reset signal RST at time T0 to reset the latch flip-flops FFn to FF2n-1. Next, the multi-mode sensor 1400a activates the window signal WIN to a high level over time points T1 and T2. The period in which the window signal WIN is activated to a high level is referred to as a window period ΔWIN. The accumulated form of the short pulses STP of the delay clock signals CK[0] to CK[n-1] during the window period ΔWIN is illustrated as CK[n-1:0]. The adder 1460 a counts the latch signals Q[0] to Q[n-1] of the delay clock signals CK[0] to CK[n-1] during the window period ΔWIN.

For example, the number of short pulses counted at time points T1 and T2 may be ‘2040’. The adder 1460a can output the output signal OUT as ‘2040’ according to the count result of the latch signals Q[0]˜Q[n-1]. Normally, the number of short pulses counted within one cycle ‘T’ of the divided clock signal DIV2 is ‘4096’ (in the T1a˜T2a section). Therefore, the presence of jitter can be determined by calculating the ratio of the number of short pulses of the output signal OUT to which the influence of jitter is reflected, ‘2040’ and ‘4096’.

In addition, the number of short pulses counted at the T3 time point and the T4 time point can be, for example, ‘2052’. The adder 1460a can output the output signal OUT as ‘2052’ according to the count result of the latch signals Q[0]˜Q[n-1]. In a normal case, the number of short pulses counted within one cycle ‘T’ of the divided clock signal DIV2 is ‘4096’ (in the T3a˜T4a section). Therefore, the presence of jitter can be determined by calculating the ratio of the number of short pulses ‘2052’ and ‘4096’ of the output signal OUT to which the influence of jitter is reflected.

The jitter sensing operation in the jitter sensing mode JS_Mode of the multi-mode sensor 1400a has been briefly described above. In the jitter sensing mode JS_Mode, the pulse generator 1420a generates the divided clock signal DIV2, the window signal WIN, and the reset signal RST based on the input clock signal FIN to generate the delay clock signals CK[0]˜CK[n-1] in the delay chain 1440a. And the multi-mode sensor 1400a counts the number of delay clock signals CK[0] to CK[n-1] included in the window period ΔWIN and provides the count as an output signal OUT. The presence of jitter can be detected based on the output signal OUT.

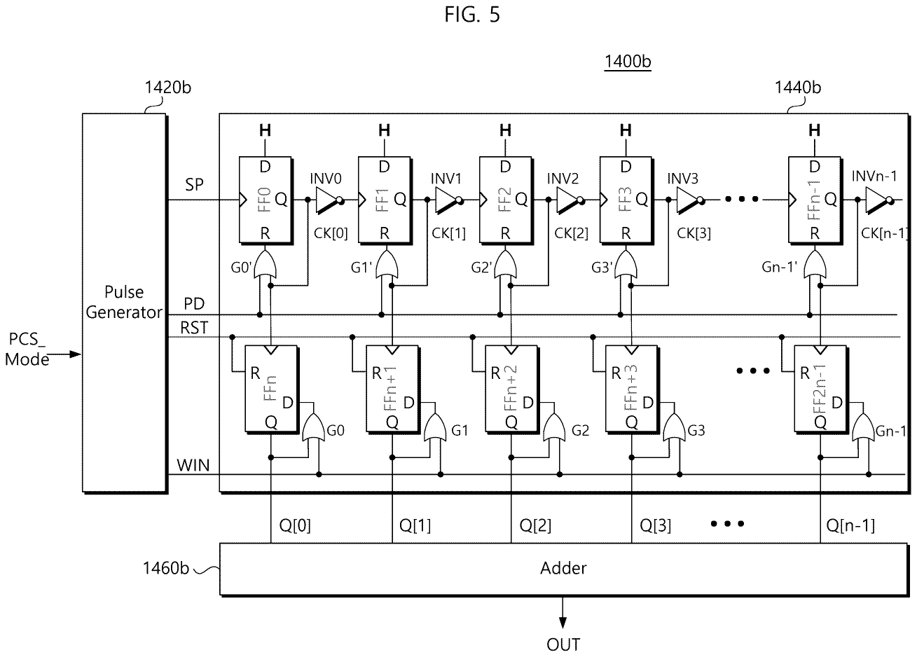

FIG. 5 is a block diagram briefly showing the setup and configuration of the multi-mode sensor of FIG. 2 in the processor corner sensing mode PCS_Mode. Referring to FIG. 5, the multi-mode sensor 1400b operates as a sensor that detects the processor corner PC of the system-on-chip (1000, see FIG. 1) in response to the processor corner sensing mode PCS_Mode. The multi-mode sensor 1400b may include a pulse generator 1420b, a delay chain 1440b, and an adder 1460b for sensing the processor corner PC.

The pulse generator 1420b generates a step pulse SP, a mode enable signal PD, a reset signal RST, and a window signal WIN in response to the processor corner sensing mode PCS_Mode. The step pulse SP, mode enable signal PD, reset signal RST, and window signal WIN generated by the pulse generator 1420b may be generated based on the input clock signal FIN or a separately provided internal clock signal.

The delay chain 1440b may receive the step pulse SP and the mode enable signal PD from the pulse generator 1420b and may generate a plurality of delay clock signals CK[0] to CK[n-1]. The delay chain 1440b may include a plurality of serially connected delay flip-flops FF0 to FFn-1, inverters INV0 to INVn-1, and gates G0′ to Gn-1′. The delay flip-flops FF0 to FFn-1 may be configured as D flip-flops that transfer the data input terminal ‘D’ to the data output terminal ‘Q’ in response to the rising edge of the input step pulse SP. Each of the delay flip-flops FF0 to FFn-1 generates the short pulse STP corresponding to a specific delay size ‘tD’ from the clock signal provided to the clock input terminal and transmits it to the data output terminal ‘Q’. At this time, the short pulses STP generated by each of the delay flip-flops FF0 to FFn-1 are output as multiple delay clock signals CK[0] to CK[n-1].

The delay clock signal CK[i] generated from one of the delay flip-flops FFi is inverted by the inverter INVi and transmitted to the clock input terminal of the next delay flip-flop FFi+1. In addition, the delay clock signal CK[i] generated from the delay flip-flop FFi is fed back to the reset input terminal ‘R’ of the flip-flop FFi for reset. In particular, in the processor corner sensing mode PCS_Mode, the delay clock signal CK[i] is selectively input to the reset input terminal ‘R’ of the flip-flop FFi according to the mode enable signal PD. When the mode enable signal PD is logic ‘1’, the reset input terminal ‘R’ of the flip-flop FFi is always input with logic ‘1’ that activates the reset by the gate Gi′ that performs the logic OR operation. On the other hand, when the mode enable signal PD is logic ‘0’, the delay clock signal CK[i] is input to the reset input terminal ‘R’ of the flip-flop FFi by the gate Gi′. Therefore, the processor corner sensing mode PCS_Mode of the present invention can be executed only when the mode enable signal PD transitions to logic ‘0’ in the pulse generator 1420b. When the mode enable signal PD from the pulse generator 1420b is provided as logic ‘0’, the circuit configuration is set to the same as the delay chain 1440a structure of FIG. 3. In addition, the delay clock signal CK[i] generated from the delay flip-flop FFi is transmitted to the clock input terminal of the lower latch flip-flop FFn+i provided for the latch.

Based on the structure including the above-described delay flip-flops FF0 to FFn-1, inverters INV0 to INVn-1, and gates G0′ to Gn-1′, the step pulse SP can be input to the first delay flip-flop FF0. The delay flip-flop FF0 generates a delay clock signal CK[0] corresponding to a specific delay size ‘tD’ for the rising edge of the step pulse SP and transmits it to the clock input terminal of the next delay flip-flop FF1. The delay flip-flop FF1 also generates a delay clock signal CK[1] with a specific delay size ‘tD’ for the delay clock signal CK[0], similar to the delay flip-flop FF0. In this way, the delay clock signals CK[0] to CK[n-1] can be generated from each of the delay flip-flops FF0 to FFn-1.

The latch flip-flops FFn to FF2n-1 and gates G0 to Gn-1 located at the bottom of the delay flip-flops FF0 to FFn-1 latch each of the delay clock signals CK[0] to CK[n-1]. The latch flip-flops FFn to FF2n-1 and gates G0 to Gn-1 perform a latch function for the delay clock signals CK[0] to CK[n-1] in response to the reset signal RST and the window signal WIN. The latch flip-flops FFn˜FF2n-1 and the gates G0˜Gn-1 transmit the latched latch signals Q[0]˜Q[n-1] to the adder 1460b.

The latch flip-flop FFn is triggered, for example, by the rising edge of the delay clock signal CK[0] and is reset by the reset signal RST. The logical OR operation of the window signal WIN and the output terminal ‘Q’ is input to the data input terminal ‘D’ of the latch flip-flop FFn by the gate G0. In short, the latch flip-flop FFn provides the delay clock signal CK[0] as the latch signal Q[0] to the adder 1460b when the window signal WIN is at a high level. The latch function of the latch flip-flop FFn and the gate G0 for delay clock signal CK[0] is performed identically by the latch flip-flops FFn+1 to FF2n-1 and the gates G1 to Gn-1.

The adder 1460b receives the latch signals Q[0] to Q[n-1] from the latch flip-flops FFn to FF2n-1. The adder 1460b provides an adder or counter function for the latch signals Q[0] to Q[n-1]. The adder 1460b can output the count result for the latch signals Q[0] to Q[n-1] as an output signal OUT. The adder 1460b can count the number of latch signals Q[0]˜Q[n-1] selected by the window signal WIN. Here, the window period ΔWIN of the window signal WIN must be provided before the rising edge of the step pulse SP is input from the first delay flip-flop FF0 and propagated to the final delay flip-flop FFn-1.

In conclusion, the multi-mode sensor 1400b counts the number of delay clock signals CK[i] existing within the window period ΔWIN in the processor corner sensing mode PCS_Mode. The number of delay clock signals CK[i] existing within the window period ΔWIN may vary depending on the processor corner PC of the delay chain 1440b. For example, if the processor corner PC of the system-on-chip 1000 corresponds to ‘FF’ where both PMOS and NMOS transistors are high-speed, a relatively large number of delay clock signals CK[i] existing within the window period ΔWIN will be detected. On the other hand, if the processor corner PC of the system-on-chip 1000 corresponds to ‘SS’ where the transistors are low-speed, a relatively small number of delay clock signals CK[i] existing within the window period ΔWIN will be detected.

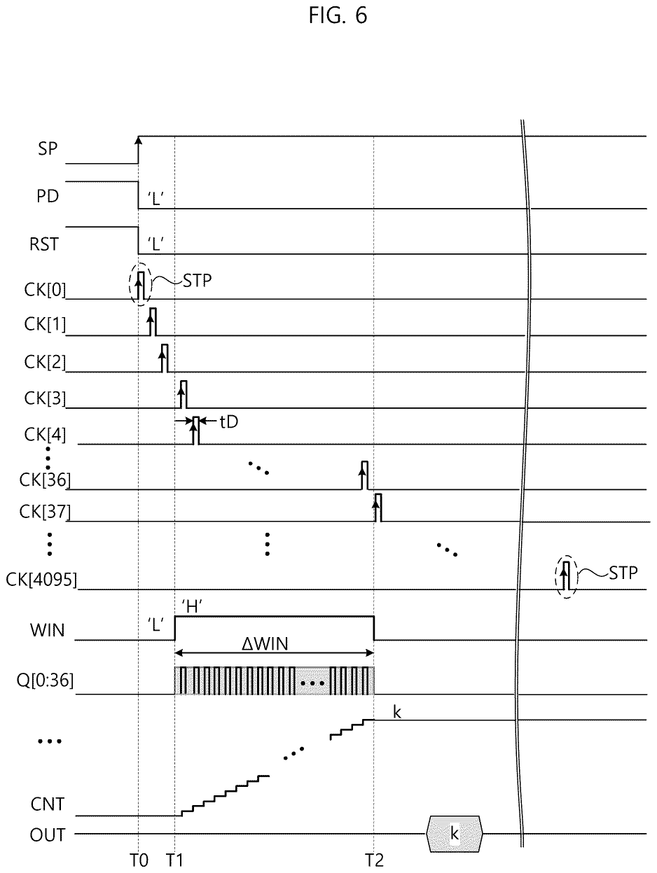

FIG. 6 is a waveform diagram showing the operation of the multi-mode sensor in the processor corner sensing mode PCS_Mode. Referring to FIG. 6, the pulse generator 1420b generates a step pulse SP, a mode enable signal PD, a reset signal RST, and a window signal WIN in response to the processor corner sensing mode PCS_Mode.

At time T0, the rising edge of the step pulse SP and the low level ‘L’ of the mode enable signal PD and the reset signal RST are activated. Then, the first delay flip-flop FF0 generates a delay clock signal CK[0] corresponding to one short pulse STP. Then, the delay clock signal CK[0] is inverted and transmitted to the clock input terminal of the next delay flip-flop FF1. In this way, each of the delay flip-flops FF0 to FFn-1 will be triggered by the step pulse SP to sequentially generate the delay clock signals CK[0] to CK[n-1]. For example, let's assume that the number ‘n’ of the delay flip-flops FF0 to FFn-1 is ‘4096’.

At time T1, the window signal WIN transitions to a high level ‘H’. And the high level ‘H’ of the window signal WIN is maintained until time T2. For example, the window signal WIN is described as having a length that selects 37 short pulses STP. However, the window period ΔWIN may preferably be set to a pulse width that can accommodate half (for example, 2048) of the delay clock signals CK[0] to CK[n-1]. The application time of the window signal WIN and the rising edge of the step pulse SP must be before reaching the last delay flip-flop FFn-1. That is, the activation time of the window signal WIN, T1 and T2, must be before the rising edge of the step pulse SP reaches the last delay flip-flop FF4095. This is because the latch signals (Q[0] to Q[36], k=37) must be counted before the rising edge of the step pulse SP reaches the last delay flip-flop FF4095 so that the processor corner PC can be detected.

During the window period ΔWIN in which the window signal WIN is maintained at a high level ‘H’, the latch signals Q[0] to Q[36] will be counted by the adder 1460b. The value counted by the adder 1460b is output as an output signal OUT. For example, the number ‘k’ of the counted latch signals Q[0] to Q[36] can be output as an output signal OUT.

At time T2, the window signal WIN transitions to a low level ‘L’. Then, the latch operation of the subsequent latch signals Q[37] to Q[4095] of the counted latch signals Q[0] to Q[36] is blocked. Although the delay clock signals CK[37] to CK[4095] are generated by the delay flip-flops FF37 to FFn-1, counting is valid only in the section selected by the window signal WIN. The number ‘k’ of the latch signals Q[0] to Q[36] counted by the adder 1460b can reflect the operating speed of the elements according to the processor corner PC of the delay flip-flops FF0 to FFn-1.

In the above, the operation of the multi-mode sensor 1400b in the processor corner sensing mode PCS_Mode is briefly described. In the processor corner sensing mode PCS_Mode, the pulse generator 1420b can generate a step pulse SP, a mode enable signal PD, a reset signal RST, and a window signal WIN regardless of the input clock signal FIN. The delay chain 1440b generates delay clock signals CK[0] to CK[n-1] according to the step pulse SP, the mode enable signal PD, the reset signal RST, and the window signal WIN. In addition, the adder 1460b counts the number ‘k’ of the delay clock signals CK[0] to CK[k-1] from among the delay clock signals CK[0] to CK[n-1] selected by the window signal WIN and outputs the count as an output signal OUT. The output count value ‘k’ can be an indicator that quantitatively represents the operating speed of the elements, i.e., the processor corner PC.

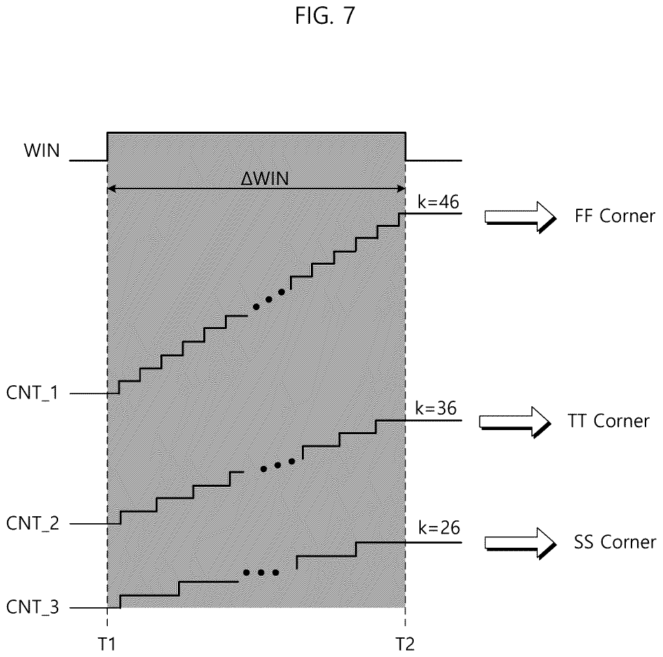

FIG. 7 is a waveform diagram exemplarily showing a method for detecting a processor corner PC according to an output signal of an adder of FIG. 6. Referring to FIG. 7, the pulse width ‘tD’ of short pulses generated by each of the delay flip-flops FF0 to FFn-1 depends on the processor corner PC. Therefore, the processor corner PC can be identified according to the number of delay clock signals CK[0] to CK[k-1] counted during the same window signal WIN period or the number ‘k’ of latch signals Q[0] to Q[k-1]. It should be noted that the values of the output signals OUT and the determination of the processor corner PC according to them are examples for the convenience of explanation and are not absolute criteria.

At time T1, the window signal WIN transitions to a high level ‘H’ and is maintained until time T2. During the window period ΔWIN in which the window signal WIN is maintained at a high level ‘H’, the latch signals Q[0] to Q[n-1] are counted by the adder 1460b. The value counted by the adder 1460b is output as an output signal OUT(=k). For example, in the case of the counted latch signals Q[0] to Q[100], the output signal OUT will be ‘k=101’.

During the window period ΔWIN, the counted number ‘k’ of the latch signals Q[0] to Q[n-1] by the first count operation CNT_1 by the adder 1460b can be ‘46’. In this case, the delay flip-flops FF0˜FFn-1 or the processor corner PC of the system-on-chip 1000 can be identified as ‘FF’ corresponding to fast for both PMOS and NMOS transistors.

During the window period ΔWIN, let's assume that the counted number ‘k’ of the latch signals Q[0]˜Q[n-1] is ‘36′by the second count operation CNT_2 by the adder 1460b. In this case, the delay flip-flops FF0˜FFn-1 or the processor corner PC of the system-on-chip 1000 can be identified as 'TT’corresponding to typical.

During the window period ΔWIN, let us assume that the counted number ‘k’ of the latch signals Q[0] to Q[n-1] is ‘26’ by the third count operation CNT_2 by the adder 1460b. In this case, the delay flip-flops FF0 to FFn-1 or the processor corner PC of the system-on-chip 1000 can be identified as ‘SS’ corresponding to slow.

As in the above-described example, the pulse width ‘tD’ of each of the delay clock signals CK[0] to CK[n-1] generated by the delay flip-flops FF0 to FFn-1 is determined according to the processor corner PC. Therefore, by counting the number of latch signals Q[0] to Q[n-1] that latched the delay clock signals CK[0] to CK[n-1] during a predetermined window period ΔWIN, the size ‘k’ of the output signal OUT that is inversely proportional to the pulse width ‘tD’ can be obtained. And, depending on the size of ‘k’, the delay flip-flops FF0 to FFn-1 or the processor corner PC of the system-on-chip 1000 can be estimated.

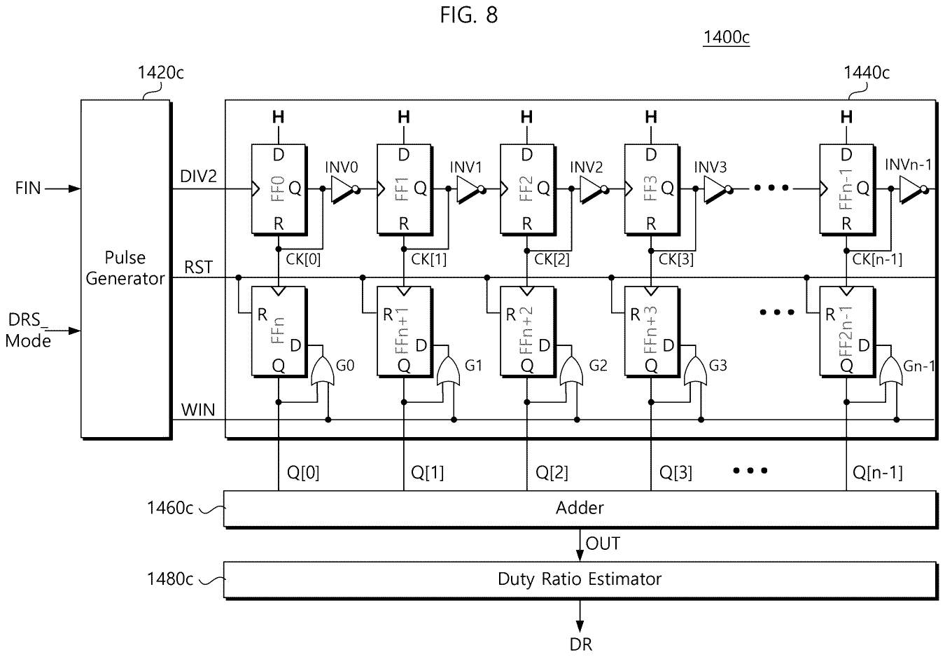

FIG. 8 is a block diagram briefly showing the setup and configuration of the multi-mode sensor of FIG. 2 in the duty ratio sensing mode. Referring to FIG. 8, the multi-mode sensor 1400c can detect the duty ratio for the input clock signal FIN in response to the duty ratio sensing mode DRS_Mode. The multi-mode sensor 1400c can include a pulse generator 1420c, a delay chain 1440c, an adder 1460c, and a duty ratio estimator 1480c for duty ratio sensing.

The pulse generator 1420c receives the input clock signal FIN in response to the duty ratio sensing mode DRS_Mode and generates a divided clock signal DIV2, a reset signal RST, and a window signal WIN. The divided clock signal DIV2, reset signal RST, and window signal WIN generated by the pulse generator 1420c can be synchronized with the input clock signal FIN. For example, the divided clock signal DIV2 can be generated through division that doubles the period of the input clock signal FIN.

Here, the window period ΔWIN, which is the pulse width of the window signal WIN, is provided as a half period (T/4) of the input clock signal FIN. The number ‘k’ of the delay clock signals CK[0] to CK[k-1] will be counted during the window period ΔWIN. And the number (n/2) of the delay clock signals CK[0] to CK[n-1] included in one period (T/2) of the input clock signal FIN in the normal case is obtained. Finally, the ratio of the number ‘k’ of the delay clock signals CK[0] to CK[k-1] counted during a half cycle (T/4) of the input clock signal FIN to the number (n/2) of the delay clock signals CK[0] to CK[k-1] during one cycle (T/2) can be determined as the duty ratio DR of the input clock signal FIN.

The delay chain 1440c can receive a divided clock signal DIV2 from the pulse generator 1420c and generate a plurality of delay clock signals CK[0] to CK[n-1]. The delay chain 1440c can include a plurality of serially connected delay flip-flops FF0 to FFn-1 and inverters INV0 to INVn-1. The structure of the delay flip-flops FF0 to FFn-1 and inverters INV0 to INVn-1 is substantially the same as those of FIG. 3 described above. Therefore, the description of the structure of the delay flip-flops FF0 to FFn-1 and inverters INV0 to INVn-1 will be omitted.

Based on the structure of the chain-type serially connected delay flip-flops FF0 to FFn-1 and inverters INV0 to INVn-1 described above, the divided clock signal DIV2 can be input to the first delay flip-flop FF0. The first delay flip-flop FF0 generates a delay clock signal CK[0] corresponding to a specific delay size ‘tD’ for the divided clock signal DIV2 and transmits it to the clock input terminal of the next delay flip-flop FF1. The delay flip-flop FF1, like the delay flip-flop FF0, generates a delay clock signal CK[1] with a specific delay size for the delay clock signal CK[0]. In this way, the delay clock signals CK[0] to CK[n-1] generated from each of the delay flip-flops FF0 to FFn-1 can be generated within one cycle of the divided clock signal DIV2.

The latch flip-flops FFn to FF2n-1 and gates G0 to Gn-1 located at the bottom of the delay flip-flops FF0 to FFn-1 latch each of the delay clock signals CK[0] to CK[n-1]. The latch flip-flops FFn to FF2n-1 and the gates G0 to Gn-1 perform a latch function for the delay clock signals CK[0] to CK[n-1] and provide the latched latch signals Q[0] to Q[n-1] to the adder 1460c. The structures of the latch flip-flops FFn to FF2n-1 and the gates G0 to Gn-1 are substantially the same as those of FIG. 3 described above.

The adder 1460c receives the latch signals Q[0] to Q[n-1] from the latch flip-flops FFn to FF2n-1. The adder 1460c provides an adder or counter function for the latch signals Q[0] to Q[n-1]. The adder 1460c can output the count result for the latch signals Q[0] to Q[n-1] as an output signal OUT. The adder 1460c can count the number of the latch signals Q[0] to Q[n-1] selected by the window signal WIN. In the duty ratio sensing mode DRS_Mode, the window period ΔWIN of the window signal WIN is provided as a half cycle (T/4) of the input clock signal FIN. The adder 1460c counts the number ‘k’ of the delay clock signals CK[0] to CK[k-1] during the half cycle (T/4) of the input clock signal FIN. Then, the adder 1460c outputs the number ‘k’ of the counted delay clock signals CK[0] to CK[k-1] as an output signal OUT.

The duty ratio estimator 1480c calculates the duty ratio DR of the input clock signal FIN using the number ‘k’ of the counted delay clock signals CK[0] to CK[k-1]. The duty ratio estimator 1480c calculates the ratio of the number ‘k’ of the counted delay clock signals CK[0] to CK[k-1] and the number (n/2) of the delay clock signals CK[0] to CK[n-1] included in a half cycle (T/4) of the input clock signal FIN provided as a fixed value. That is, the duty ratio estimator 1480c calculates the duty ratio DR of the input clock signal FIN. The duty ratio DR of the input clock signal FIN calculated by the duty ratio estimator 1480c can be output to the outside of the multi-mode sensor 1400c. The duty ratio estimator 1480c may be optionally included or excluded in the multi-mode sensor 1400c. The function of the duty ratio estimator 1480c using the number ‘k’ of counted delay clock signals CK[0] to CK[k-1] may be performed in an external function block (e.g., CPU) or management processor of the multi-mode sensor 1400c.

As described above, the multi-mode sensor 1400c may detect the duty ratio DR for the input clock signal FIN in response to the duty ratio sensing mode DRS_Mode. The multi-mode sensor 1400c can provide a duty ratio DR as a ratio of the number ‘k’ of delay clock signals CK[0] to CK[k-1] counted during a half cycle (T/2) of an input clock signal FIN to the number (n/2) of delay clock signals CK[0] to CK[k-1] during one cycle (T).

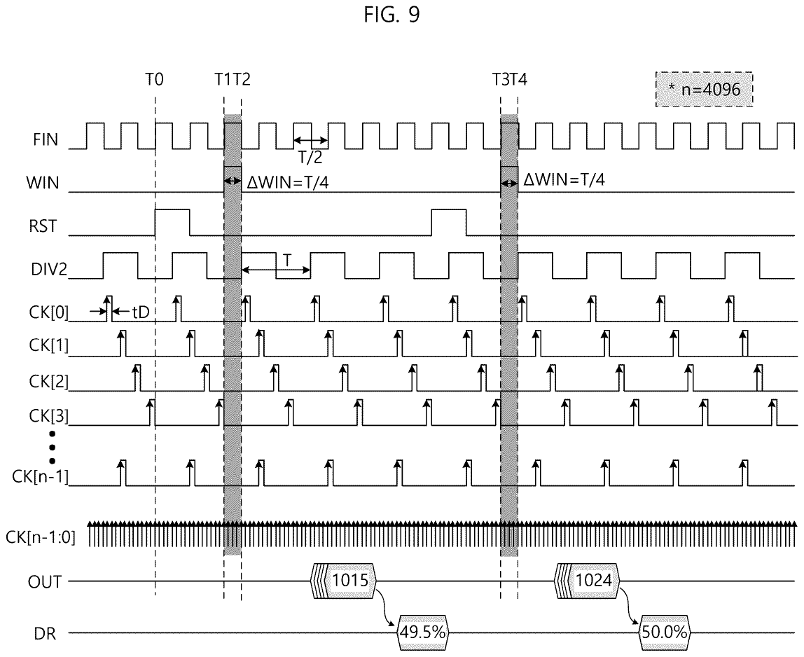

FIG. 9 is a waveform diagram showing the operation of the multi-mode sensor in the duty ratio sensing mode DRS_Mode. Referring to FIG. 9, the divided clock signal DIV2 sequentially passes through the delay flip-flops FF0 to FFn-1 to generate the delay clock signals CK[0] to CK[n-1]. For the convenience of explanation, it is assumed that the number ‘n’ of the delay flip-flops FF0 to FFn-1 is ‘4096’. In addition, the window signal WIN is provided with a pulse width (=ΔWIN) of a half cycle (T/4) of the input clock signal FIN. Under these conditions, the number ‘k’ of the delay clock signals CK[0] to CK[k-1] will be counted during the window period ΔWIN. Finally, the ratio of the number ‘k’ of the delay clock signals CK[0] to CK[k-1] counted during a half cycle (T/4) of the input clock signal FIN to the number (n/2) of the delay clock signals CK[0] to CK[k-1] during one cycle (T/2) can be calculated as the duty ratio DR of the input clock signal FIN.

Each of the delay flip-flops FF0 to FFn-1 generates short pulses STP with a cycle of the divided clock signal DIV2. That is, one short pulse STP can be generated per cycle (T) of the divided clock signal DIV2. The short pulse STP generated from the first delay flip-flop FF0 corresponds to the delay clock signals CK[0], and the short pulse STP generated from the delay flip-flop FF1 corresponds to CK[1]. And the short pulse STP generated from the last delay flip-flop FFn-1 corresponds to CK[n-1]. Therefore, if the number of short pulses of each of the delay clock signals CK[0] to CK[n-1] is counted within one cycle (T) of the divided clock signal DIV2, it will be ‘4096’ corresponding to the number of delay flip-flops FF0 to FFn-1.

For duty ratio sensing, the pulse generator 1420c activates the reset signal RST at time T0 to reset the latch flip-flops FFn to FF2n-1. Then, the multi-mode sensor 1400c activates the window signal WIN to a high level ‘H’ over time T1 and T2. The accumulated form of the short pulses STP of the delay clock signals CK[0]˜CK[n-1] during the window period ΔWIN is depicted as CK[n-1:0]. The adder 1460c counts the latch signals Q[0]˜Q[k-1] of the delay clock signals CK[0]˜CK[k-1] during the window period ΔWIN.

For example, assuming that the number of short pulses ‘k’ counted at time T1 and time T2 is ‘1015’. The adder 1460c can output the output signal OUT as ‘1015’ according to the count result of the latch signals Q[0]˜Q[k-1]. Normally, the number of short pulses counted within one period (T/2) of the input clock signal FIN is ‘2048’. Therefore, the duty ratio DR can be provided as a ratio 49.5% of the short pulse counts ‘1015’ and ‘2048’ of the output signal OUT.

On the other hand, assuming that the number of short pulses ‘k’ counted at time T3 and T4 is ‘1024’, the adder 1460c can output the output signal OUT as ‘1024’ according to the count results of the latch signals Q[0] to Q[k-1]. Therefore, the duty ratio DR can be calculated as a ratio 50.0% of the short pulse counts ‘1024’ and ‘2048’ of the output signal OUT.

Above, the duty ratio DR sensing operation in the duty ratio sensing mode (DRS_Mode) of the multi-mode sensor 1400c has been briefly described. In the duty ratio sensing mode (DRS_Mode), the pulse generator 1420c can calculate the duty ratio DR of the input clock signal FIN by counting the number of delay clock signals CK[0] to CK[n-1] included in the window period ΔWIN.

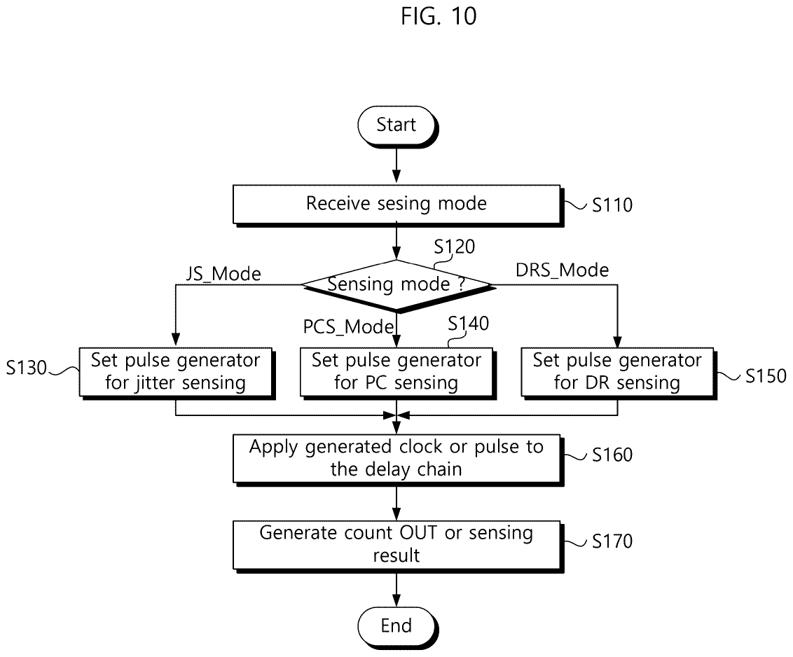

FIG. 10 is a flowchart showing an operation procedure according to a sensing mode (S_Mode) of a multi-mode sensor according to an embodiment of the present invention. Referring to FIG. 10, the multi-mode sensor 1400 can execute one of a plurality of sensing modes in response to a sensing mode.

In step S110, the multi-mode sensor 1400 receives one of a plurality of sensing modes. For example, the multi-mode sensor 1400 receives one of a jitter sensing mode (JS_Mode), a processor corner sensing mode (PCS_Mode), and a duty ratio sensing mode (DRS_Mode).

In step S120, the multi-mode sensor 1400 performs an operation branch according to the received sensing mode. If the received sensing mode is a jitter sensing mode (JS_Mode), the procedure moves to step S130. If the received sensing mode is the processor corner sensing mode (PCS_Mode), the procedure moves to step S140. If the received sensing mode is the duty ratio sensing mode (DRS_Mode), the procedure moves to step S150.

In step S130, the multi-mode sensor 1400 sets the pulse generator 1420 to execute the jitter sensing mode (JS_Mode). The pulse generator 1420 receives the input clock signal FIN. Then, the pulse generator 1420 generates a divided clock signal DIV2, a reset signal RST, and a window signal WIN from the input clock signal FIN.

In step S140, the multi-mode sensor 1400 sets the pulse generator 1420 to execute the processor corner sensing mode (PCS_Mode). The pulse generator 1420 generates a step pulse SP, a mode activation signal PD, a reset signal RST, and a window signal WIN for the processor corner sensing mode (PCS_Mode).

In step S150, the multi-mode sensor 1400 sets the pulse generator 1420 to execute the duty ratio sensing mode (DRS_Mode). The pulse generator 1420 receives an input clock signal FIN for the duty ratio sensing mode (DRS_Mode) and generates a divided clock signal DIV2, a reset signal RST, and a window signal WIN.

In step S160, the multi-mode sensor 1400 applies a clock signal or pulse generated according to the sensing mode to the delay chain 1440. Then, the delay chain 1440 can generate a plurality of delay clock signals CK[0] to CK[n-1] in response to the clock signal or pulse from the pulse generator 1420. The delay clock signals CK[0] to CK[n-1] are latched into latch signals Q[0] to Q[n-1]. Then, the delay chain 1440 selects latch signals Q[0] to Q[n-1] as much as the pulse width of the window signal WIN according to the sensing mode and transmits them to the adder 1460.

In step S170, the adder 1460 counts the latch signals Q[0] to Q[n-1] from the delay chain 1440 and outputs the count result as an output signal OUT. The output signal OUT may be the presence or absence of jitter or the number of short pulses in the jitter sensing mode (JS_Mode). The output signal OUT may correspond to the number of short pulses in a predetermined section in the processor corner sensing mode (PCS_Mode). And in the duty ratio sensing mode (DRS_Mode), the output signal OUT may be the number of short pulses counted during one cycle (T/2) of the input clock signal FIN or the duty ratio itself.

As described above, the multi-mode sensor 1400 of the present invention may execute any one of a plurality of sensing functions depending on the input sensing mode (S_Mode). Therefore, in the system-on-chip 1000 including the multi-mode sensor 1400, the chip area occupied by the sensors may be reduced, and the power efficiency of the sensors may be improved.

The above are specific embodiments for carrying out the present invention. In addition to the above-described embodiments, the present invention may include simple design changes or easily changeable embodiments. In addition, the present invention will include techniques that can be easily modified and implemented using the embodiments. Therefore, the scope of the present invention should not be limited to the above-described embodiments, and should be defined by the claims and equivalents of the claims of the present invention as well as the claims to be described later.

What is claimed is:

1. A multi-mode sensor, comprising:
a pulse generator configured to generate at least one of a clock signal, a step pulse signal, and a window signal according to a sensing mode;
a delay chain configured to select and output delay clock signals that are transmitted through each of a plurality of delay elements by being triggered by the clock signal or the step pulse signal as much as a pulse width of the window signal; and
an adder configured to count and output a number of selected short pulses,
wherein a sensing mode includes one of a jitter sensing mode for sensing jitter of the clock signal, a processor corner sensing mode for sensing processor corner of the plurality of delay elements, and a duty ratio sensing mode for sensing a duty ratio of the clock signal.

2. The multi-mode sensor of claim 1, wherein the pulse generator supplies the clock signal to a first element of the plurality of delay elements in response to the jitter sensing mode or the duty ratio sensing mode.

3. The multi-mode sensor of claim 2, wherein the pulse generator supplies the step pulse signal to the first element of the plurality of delay elements in response to the processor corner sensing mode.

4. The multi-mode sensor of claim 1, wherein the delay chain comprises:
delay flip-flops connected in series, each of which is provided as the plurality of delay elements and outputs the short pulses as delay clock signals; and
latch flip-flops configured to latch the delay clock signals, select the latched delay clock signals according to the window signal and to output latch signals.

5. The multi-mode sensor of claim 4, wherein in the jitter sensing mode, the pulse width of the window signal corresponds to a half cycle of the clock signal, and in the duty ratio sensing mode, the pulse width of the window signal corresponds to a quarter cycle of the clock signal.

6. The multi-mode sensor of claim 5, wherein the pulse width of the window signal in the processor corner sensing mode is smaller than a time obtained by multiplying the pulse width of the short pulses by number of the delay flip-flops.

7. The multi-mode sensor of claim 4, wherein the pulse generator is configured to generate a reset signal for resetting the latch flip-flops.

8. A multi-mode sensing method of a sensor mounted on a system-on-chip, comprising:
receiving one of a plurality of sensing modes;
generating at least one of a clock signal, a step pulse signal, and a window signal according to the received sensing mode;
generating short pulses that are triggered by the clock signal or the step pulse signal to propagate through a plurality of delay elements;
selecting delay clock signals delayed by the plurality of delay elements by a pulse width of the window signal; and
counting and outputting a number of the selected delay clock signals.

9. The method of claim 8, wherein the sensing mode corresponds to one of a jitter sensing mode for sensing jitter of the clock signal, a processor corner sensing mode for sensing a processor corner of the plurality of delay elements, and a duty ratio sensing mode for sensing a duty ratio of the clock signal.

10. The method of claim 9, wherein the plurality of delay elements each include serially connected D flip-flops that output the short pulses as delay clock signals.

11. The method of claim 9, wherein the pulse width of the window signal corresponds to a half cycle of the clock signal in the jitter sensing mode, and the pulse width of the window signal corresponds to a quarter cycle of the clock signal in the duty ratio sensing mode.

12. The method of claim 8, further comprising:
latching each of the delay clock signals and accumulating latched delay clock signals on a time axis.

13. The method of claim 12, further comprising:
outputting pulses selected by the window signal among the delay clock signals accumulated on the time axis as latch signals.

14. The method of claim 11, further comprising:
calculating the duty ratio of the clock signal based on the number of the counted delay clock signals.

15. A system-on-chip, comprising:
a central processing unit; and
a multi-mode sensor configured to execute one of a plurality of sensing modes according to a sensing mode provided from the central processing unit and output an execution result of the one of the sensing modes as an output signal,
wherein the multi-mode sensor comprises:
a pulse generator configured to generate at least one of a clock signal, a step pulse signal, and a window signal according to the sensing mode;
a delay chain configured to select and output delay clock signals that are transmitted through each of a plurality of delay elements by being triggered by the clock signal or the step pulse signal as much as a pulse width of the window signal; and
an adder configured to count a number of the selected delay clock signals to output the number of the selected delay clock signals as the output signal,
wherein the plurality of sensing modes include a jitter sensing mode for sensing jitter of the clock signal, a processor corner sensing mode for sensing a processor corner of the plurality of delay elements, and a duty ratio sensing mode for sensing a duty ratio of the clock signal.

16. The system-on-chip of claim 15, wherein each of the plurality of delay elements includes a delay flip-flop and an inverter,
wherein the clock signal or the step pulse signal is input to a clock input terminal of the delay flip-flop, a data input terminal of the delay flip-flop is fixed to a high level, and a data output terminal of the delay flip-flop is connected to the inverter and a reset terminal of the delay flip-flop.

17. The system-on-chip of claim 16, wherein the delay chain further includes a latch flip-flop for latching a delay clock signal output from the delay flip-flop in response to the window signal.

18. The system-on-chip of claim 15, wherein the pulse generator is configured to supply the clock signal to a first element among the plurality of delay elements in response to the jitter sensing mode or the duty ratio sensing mode.

19. The system-on-chip of claim 18, wherein, in response to the processor corner sensing mode, the pulse generator is configured to supply the step pulse signal to a first element among the plurality of delay elements and generate a mode enable signal, and the delay chain includes a logic gate that provides either a logic high level or a delay clock signal to a reset input terminal of a delay flip-flop based on the mode enable signal.

20. The system-on-chip of claim 19, wherein in the jitter sensing mode, the pulse width of the window signal corresponds to a half cycle of the clock signal, and in the duty ratio sensing mode, the pulse width of the window signal corresponds to a quarter cycle of the clock signal.
